(19) United States
(12) Patent Application Publication
(10) Pub. No.: US 2026/0040748 A1
(43) Pub. Date: Feb. 5, 2026

(54) DISPLAY APPARATUS

(71) Applicant: AUO Corporation, Hsinchu City (TW)

(72) Inventors: Chia-An Lee, Hsinchu City (TW); Yu-Hsin Huang, Hsinchu City (TW); Yi-Hong Chen, Hsinchu City (TW); YinYu Chen, Hsinchu City (TW); Wen-Wei Yang, Hsinchu City (TW); Kuan-Heng Lin, Hsinchu City (TW)

(73) Assignee: AUO Corporation, Hsinchu City (TW)

(21) Appl. No.: 19/238,549

(22) Filed: Jun. 16, 2025

(30) Foreign Application Priority Data
Jul. 31, 2024 (TW) 113128602

(51) Int. Cl. H10H 29/855; H01L 25/16; H10H 20/821; H10H 29/49

(52) U.S. Cl. CPC H10H 29/855; H01L 25/167; H10H 20/821; H10H 29/49

(57) ABSTRACT

A display apparatus includes a driving backplane, a pixel unit, an opposite substrate, and a spacer unit. The pixel unit includes a plurality of light-emitting elements. The light-emitting elements are disposed on the driving backplane and electrically connected to the driving backplane. The light-emitting elements include a first light-emitting element. The opposite substrate is disposed opposite to the driving backplane. The spacer unit is disposed on the opposite substrate. The spacer unit overlaps with the pixel unit. The spacer unit includes a first spacer. A surface of the first spacer and a light-emitting surface of the first light-emitting element abut each other. There is a first low refractive index layer between the surface of the first spacer and the light-emitting surface of the first light-emitting element. A refractive index of the first low refractive index layer is less than a refractive index of the first spacer.

### CROSS-REFERENCE TO RELATED APPLICATION

This application claims the priority benefit of Taiwan application serial no. 113128602, filed on Jul. 31, 2024. The entirety of the above-mentioned patent application is hereby incorporated by reference herein and made a part of this specification.

### BACKGROUND

### Technical Field

The disclosure relates to an optoelectronic apparatus, and particularly relates to a display apparatus.

### Description of Related Art

A light-emitting diode display panel includes a driving backplane and a plurality of light-emitting diode elements transferred onto the driving backplane. Inheriting the characteristics of light-emitting diodes, the light-emitting diode display panel has advantages such as power saving, high efficiency, high brightness, and fast response time. In addition, compared with organic light-emitting diode display panels, light-emitting diode display panels also have advantages such as easy color adjustment, long illumination life, and no image burn-in. Therefore, light-emitting diode display panels are considered as the next generation display technology. However, the forward luminous efficacy of light-emitting diode elements is poor, resulting in excessive power consumption of light-emitting diode display panels.

### SUMMARY

The disclosure provides a display apparatus with good forward luminous efficacy.

A display apparatus of the disclosure includes a driving backplane, a pixel unit, an opposite substrate, and a spacer unit. The pixel unit includes a plurality of light-emitting elements. The plurality of light-emitting elements are disposed on the driving backplane and electrically connected to the driving backplane. The plurality of light-emitting elements at least include a first light-emitting element. The opposite substrate is disposed opposite to the driving backplane. The spacer unit is disposed on the opposite substrate. The spacer unit overlaps with the pixel unit. The spacer unit at least includes a first spacer. A surface of the first spacer and a light-emitting surface of the first light-emitting element abut each other. There is a first low refractive index layer between the surface of the first spacer and the light-emitting surface of the first light-emitting element. A refractive index of the first low refractive index layer is less than a refractive index of the first spacer.

### BRIEF DESCRIPTION OF THE DRAWINGS

FIG. 1 is a schematic cross-sectional view of a display apparatus 10 according to an embodiment of the disclosure.

FIG. 2 shows the ratio I₁/I₀ of the forward brightness I₁ of the display apparatus 10 of an embodiment of the disclosure with the spacer 142 having various heights H (marked in FIG. 1) and various first angles T1/second angles T2 to the forward brightness I₀ of a display apparatus of a comparative example.

FIG. 3 shows the ratio R₁/R₀ of the reflectivity R₁ of the display apparatus 10 of an embodiment of the disclosure with the spacer 142 having various heights H and various first angles T1/second angles T2 to the reflectivity R₀ of a display apparatus of a comparative example.

FIG. 4 shows the ratio i₁/i₀ of the brightness i₁ of the display apparatus 10 of an embodiment of the disclosure with the spacer 142 having a height H-3 μm and a first angle T1/second angle T2=70° at various angles of view to the brightness i₀ of a display apparatus of a comparative example at the same angles of view.

FIG. 5 shows the ratio i₁/i₀ of the brightness i₁ of the display apparatus 10 of an embodiment of the disclosure with the spacer 142 having a height H=3 μm and a first angle T1/second angle T2=90° at various angles of view to the brightness i₀ of a display apparatus of a comparative example at the same angles of view.

FIG. 6 shows the ratio i₁/i₀ of the brightness i₁ of the display apparatus 10 of an embodiment of the disclosure with the spacer 142 having a height H=3 μm and a first angle T1/second angle T2=110° at various angles of view to the brightness i₀ of a display apparatus of a comparative example at the same angles of view.

FIG. 7 shows the ratio i/i₀ of the brightness i₁ of the display apparatus 10 of an embodiment of the disclosure with the spacer 142 having a height H=11 μm and a first angle T1/second angle T2=70° at various angles of view to the brightness i₀ of a display apparatus of a comparative example at the same angles of view.

FIG. 8 shows the ratio i₁/i₀ of the brightness i₁ of the display apparatus 10 of an embodiment of the disclosure with the spacer 142 having a height H=11 μm and a first angle T1/second angle T2=90° at various angles of view to the brightness i₀ of a display apparatus of a comparative example at the same angles of view.

FIG. 9 shows the ratio i₁/i₀ of the brightness i₁ of the display apparatus 10 of an embodiment of the disclosure with the spacer 142 having a height H=11 μm and a first angle T1/second angle T2=110° at various angles of view to the brightness i₀ of a display apparatus of a comparative example at the same angles of view.

FIG. 10 presents in a columnar method the ratio I₁/I₀ of the forward brightness I₁ of the display apparatus 10 of an embodiment of the disclosure with the spacer 142 having various heights H and various first angles T1/second angles T2 to the forward brightness I₀ of a display apparatus of a comparative example.

FIG. 11 presents in a columnar method the ratio I₁/I₀ of the forward brightness I₁ of the display apparatus 10 of an embodiment of the disclosure with the spacer 142 having various heights H and various first angles T1/second angles T2 to the forward brightness I₀ of a display apparatus of a comparative example.

FIG. 12 is a schematic front view of a display apparatus 10A according to another embodiment of the disclosure.

FIG. 13 is a schematic cross-sectional view of a display apparatus 10A according to another embodiment of the disclosure.

FIG. 14 is a schematic cross-sectional view of a display apparatus 10A according to

another embodiment of the disclosure.

FIG. 15 shows the relationship between the angle of view and the ratio i₁/i₀ of the display apparatus 10 of another embodiment of the disclosure when the first angle T1, the second angle T2, the third angle T3, and the fourth angle T4 of its light-emitting element 122 are at various values.

FIG. 16 is a schematic front view of a display apparatus 10B according to yet another embodiment of the disclosure.

FIG. 17 is a schematic cross-sectional view of a display apparatus 10B according to yet another embodiment of the disclosure.

FIG. 18 is a schematic cross-sectional view of a display apparatus 10B according to yet another embodiment of the disclosure.

FIG. 19 shows the relationship between the angle of view and the ratio i₁/i₀ of the display apparatus 10B of yet another embodiment of the disclosure when the first angle T1, the second angle T2, the third angle T3, and the fourth angle T4 of its light-emitting element 122 are at various values.

FIG. 20 is a schematic cross-sectional view of a display apparatus 10C according to still another embodiment of the disclosure.

FIG. 21 is a schematic cross-sectional view of a display apparatus 10D according to an embodiment of the disclosure.

FIG. 22 is a schematic cross-sectional view of a display apparatus 10E according to another embodiment of the disclosure.

FIG. 23 is a schematic cross-sectional view of a display apparatus 10E according to another embodiment of the disclosure.

FIG. 24 shows the relationship between the ratio I₁/I₀ and the difference value ΔDw between the width PS_W of the spacer 142 and the width LED_W of the light-emitting element 122 in the width direction dw of the light-emitting element 122, and the difference value ΔDl between the length PS_L of the spacer 142 and the length LED_L of the light-emitting element 122 in the length direction dl of the light-emitting element 122.

FIG. 25 shows the ratio i₁/i₀ of the brightness i₁ of the display apparatus 10E of another embodiment of the disclosure where ΔDw=+2 μm and ΔDl=+2 μm at various angles of view to the brightness i₀ of a display apparatus of a comparative example at the same angles of view.

FIG. 26 is a schematic cross-sectional view of a display apparatus 10F according to yet another embodiment of the disclosure.

FIG. 27 is a schematic cross-sectional view of a display apparatus 10F according to yet another embodiment of the disclosure.

FIG. 28 shows the relationship between the ratio I₁/I₀ and the offset amount Sw of the light-emitting element 122 and the spacer 142 in the width direction dw of the light-emitting element 122, and the offset amount Sl of the light-emitting element 122 and the spacer 142 in the length direction dl of the light-emitting element 122.

FIG. 29 is a schematic cross-sectional view of a display apparatus 10G according to still another embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like parts.

It will be understood that when a component such as a layer, a film, a region, or a substrate is referred to as being “on” or “connected to” another component, it may be directly on or connected to the other another component, or intermediate components may also exist there between. Comparatively, when a component is referred to be “directly on” or “directly connected” to another, none other intermediate component exists there between. As used herein, the “connection” may refer to physical and/or electrical connection. Furthermore, “electrical connection” of two components may refer to that other components may exist between the two components.

Considering the discussed measurement and a specific number of errors associated with the measurement (i.e., limitations of the measurement system), the terms “about”, “substantial” or “approximate” used herein include the related value and an average within an acceptable deviation range for a specific value determined by those skilled in the art. For example, “about” may represent a range within one or a plurality of standard deviations of the related value, or within ±30%, ±20%, ±10%, ±5%. Moreover, the “about”, “substantially”, or “approximate” used herein may be a more acceptable deviation range or standard deviation based on optical properties, etching properties, or other properties, and not one standard deviation may be applied to all properties.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

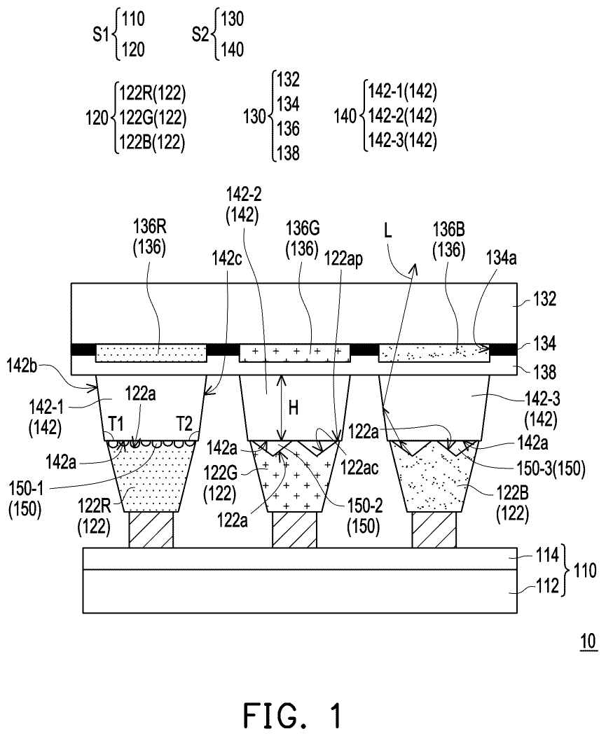

FIG. 1 is a schematic cross-sectional view of a display apparatus 10 according to an embodiment of the disclosure. Referring to FIG. 1, the display apparatus 10 includes a driving backplane 110. The driving backplane 110 may include a substrate 112. For example, in some embodiments, the material of the substrate 112 may be glass, quartz, organic polymer, or other applicable materials.

The driving backplane 110 also includes a driving circuit structure 114, disposed on the substrate 112. For example, in some embodiments, the driving circuit structure 114 may include data lines (not illustrated), scan lines (not illustrated), power lines (not illustrated), common lines (not illustrated) and a plurality of sub-pixel driving circuits (not illustrated), where each sub-pixel driving circuit may include a first transistor (not illustrated), a second transistor (not illustrated) and a capacitor (not illustrated). A first terminal of the first transistor is electrically connected to the data line, a control terminal of the first transistor is electrically connected to the scan line, a second terminal of the first transistor is electrically connected to a control terminal of the second transistor, a first terminal of the second transistor is electrically connected to the power line, and the capacitor is electrically connected to the second terminal of the first transistor and the first terminal of the second transistor. However, the disclosure is not limited thereto. In other embodiments, the sub-pixel driving circuit may also be other types of circuit.

In some embodiments, the driving circuit structure 114 also includes a plurality of pad groups (not illustrated), respectively electrically connected to the plurality of sub-pixel driving circuits. For example, in some embodiments, each pad group may include a first pad (not illustrated) and a second pad (not illustrated) that are structurally separated from each other, where one of the first pad and the second pad may be electrically connected to a second terminal of the second transistor of a corresponding sub-pixel driving circuit, and the other one of the first pad and the second pad may be electrically connected to the common line, but the disclosure is not limited thereto.

The display apparatus 10 also includes a plurality of pixel units 120. FIG. 1 illustrates

one pixel unit 120 as representative. Each pixel unit 120 includes a plurality of light-emitting elements 122, where the plurality of light-emitting elements 122 are disposed on the driving backplane 110 and electrically connected to the driving backplane 110. Specifically, in some embodiments, the plurality of light-emitting elements 122 are respectively electrically connected to the plurality of pad groups of the driving backplane 110. In some embodiments, the plurality of light-emitting elements 122 of each pixel unit 120 may include a first light-emitting element 122R, a second light-emitting element 122G, and a third light-emitting element 122B, where the first light-emitting element 122R, the second light-emitting element 122G, and the third light-emitting element 122B are respectively used to emit a first colored light, a second colored light, and a third colored light. In some embodiments, the first colored light, the second colored light, and the third colored light are, for example, red light, green light, and blue light respectively, but the disclosure is not limited thereto.

The display apparatus 10 also includes an opposite substrate 130, disposed opposite to the driving backplane 110. For example, in some embodiments, the opposite substrate 130 may include a base 132, a light-shielding pattern layer 134, and a plurality of color filter patterns 136, where the light-shielding pattern layer 134 is disposed on the base 132 and has a plurality of openings 134a respectively located above the plurality of light-emitting elements 122, and the plurality of color filter patterns 136 are respectively disposed in the plurality of openings 134a of the light-shielding pattern layer 134. In some embodiments, the plurality of color filter patterns 136 may include a first color filter pattern 136R, a second color filter pattern 136G, and a third color filter pattern 136B that respectively overlap with the first light-emitting element 122R, the second light-emitting element 122G, and the third light-emitting element 122B. For example, in some embodiments, the first color filter pattern 136R, the second color filter pattern 136G, and the third color filter pattern 136B are, for example, red filter pattern, green filter pattern, and blue filter pattern respectively, but the disclosure is not limited thereto.

The display apparatus 10 also includes a plurality of spacer units 140. FIG. 1 illustrates one spacer unit 140 as an example. The spacer unit 140 is disposed on the opposite substrate 130. In some embodiments, the opposite substrate 130 may also include a planarization layer 138 covering the plurality of color filter patterns 136, and the spacer unit 140 may selectively be disposed on the planarization layer 138. The spacer unit 140 overlaps with the pixel unit 120.

Specifically, in some embodiments, each spacer unit 140 may include a plurality of spacers 142 separated from each other, where the plurality of spacers 142 of each spacer unit 140 respectively overlap with the plurality of light-emitting elements 122 of a corresponding pixel unit 120. A surface 142a of each spacer 142 and a light-emitting surface 122a of a corresponding light-emitting element 122 abut each other, and there is a low refractive index layer 150 between the surface 142a of each spacer 142 and the light-emitting surface 122a of the corresponding light-emitting element 122, and a refractive index of the low refractive index layer 150 is less than a refractive index of the spacer 142.

For example, in some embodiments, the plurality of spacers 142 of each spacer unit 140 may include a first spacer 142-1, a second spacer 142-2, and a third spacer 142-3 that are separated from each other. The surface 142a of the first spacer 142-1 and the light-emitting surface 122a of the first light-emitting element 122R abut each other, there is a first low refractive index layer 150-1 between the surface 142a of the first spacer 142-1 and the light-emitting surface 122a of the first light-emitting element 122R, and a refractive index of the first low refractive index layer 150-1 is less than a refractive index of the first spacer 142-1. The surface 142a of the second spacer 142-2 and the light-emitting surface 122a of the second light-emitting element 122G abut each other, there is a second low refractive index layer 150-2 between the surface 142a of the second spacer 142-2 and the light-emitting surface 122a of the second light-emitting element 122G, and a refractive index of the second low refractive index layer 150-2 is less than a refractive index of the second spacer 142-2. The surface 142a of the third spacer 142-3 and the light-emitting surface 122a of the third light-emitting element 122B abut each other, there is a third low refractive index layer 150-3 between the surface 142a of the third spacer 142-3 and the light-emitting surface 122a of the third light-emitting element 122B, and a refractive index of the third low refractive index layer 150-3 is less than a refractive index of the third spacer 142-3. In some embodiments, preferably, the difference value between the refractive index of each spacer 142 and the refractive index of a corresponding low refractive index layer 150 is greater than 0.3, but the disclosure is not limited thereto.

A light-emitting element array substrate S1 includes the driving backplane 110 and the plurality of pixel units 120 fixed on the driving backplane 110. A spacer array substrate S2 includes the opposite substrate 130 and the plurality of spacer units 140 formed on the opposite substrate 130. In some embodiments, the light-emitting element array substrate S1 and the spacer array substrate S2 may be assembled in a vacuum environment to form the display apparatus 10, and the low refractive index layer 150 between the surface 142a of each spacer 142 and the light-emitting surface 122a of a corresponding light-emitting element 122 may be a vacuum layer. However, the disclosure is not limited thereto. In other embodiments, the low refractive index layer 150 between the surface 142a of each spacer 142 and the light-emitting surface 122a of a corresponding light-emitting element 122 may also be a solid low refractive index material layer. In some embodiments, the material of the spacer 142 is, for example, photoresist, but the disclosure is not limited thereto.

In some embodiments, the light-emitting surface 122a of each light-emitting element 122 may have a plurality of protrusions 122ap and a plurality of recesses 122ac defined by the plurality of protrusions 122ap, a corresponding spacer 142 may contact the plurality of protrusions 122ap of the light-emitting surface 122a of the light-emitting element 122, and at least a portion of the low refractive index layer 150 is disposed in the plurality of recesses 122ac of the light-emitting surface 122a of the light-emitting element 122.

Each spacer 142 has a first sidewall 142b and a second sidewall 142c opposite to each other. The surface 142a of the spacer 142 and the first sidewall 142b of the spacer 142 contain a first angle T1 within the material of the spacer 142. The surface 142a of the spacer 142 and the second sidewall 142c of the spacer 142 contain a second angle T2 within the material of the spacer 142. In some embodiments, the first angle T1 and the second angle T2 may selectively be the same, but the disclosure is not limited thereto. In other embodiments, the first angle T1 and the second angle T2 may not be the same, which will be illustrated with examples in conjunction with other FIG. in the following paragraphs.

In some embodiments, preferably, the first angle T1 and/or the second angle T2 is greater than or equal to 70° and less than or equal to 110°, but the disclosure is not limited thereto. In some embodiments, the first angle T1 and/or the second angle T2 may selectively be greater than 90°. That is, in some embodiments, the first angle T1 and/or the second angle T2 may selectively be an obtuse angle, but the disclosure is not limited thereto. In other embodiments, the first angle T1 and/or the second angle T2 may also be an acute angle and/or a right angle.

It is worth mentioning that, in addition to fixing and uniformizing the cell gap between the light-emitting element array substrate S1 and the spacer array substrate S2, the spacer 142 may also be used as a light guide column. The spacer 142 may guide a light beam L emitted from the light-emitting element 122 to concentrate in the forward direction, increasing the forward luminous efficacy of the light-emitting element 122. Furthermore, the trapezoidal structure of the spacer 142 has the benefit of increasing the forward luminous efficacy of the light-emitting element 122, and the spacer 142 does not need to have a convex lens structure, thus having the advantage of easy fabrication. Moreover, since the spacer 142 and the light-emitting element 122 abut each other, it may prevent the light-emitting element 122 from being disconnected from the driving backplane 110 due to excessive eutectic reaction during reliability testing.

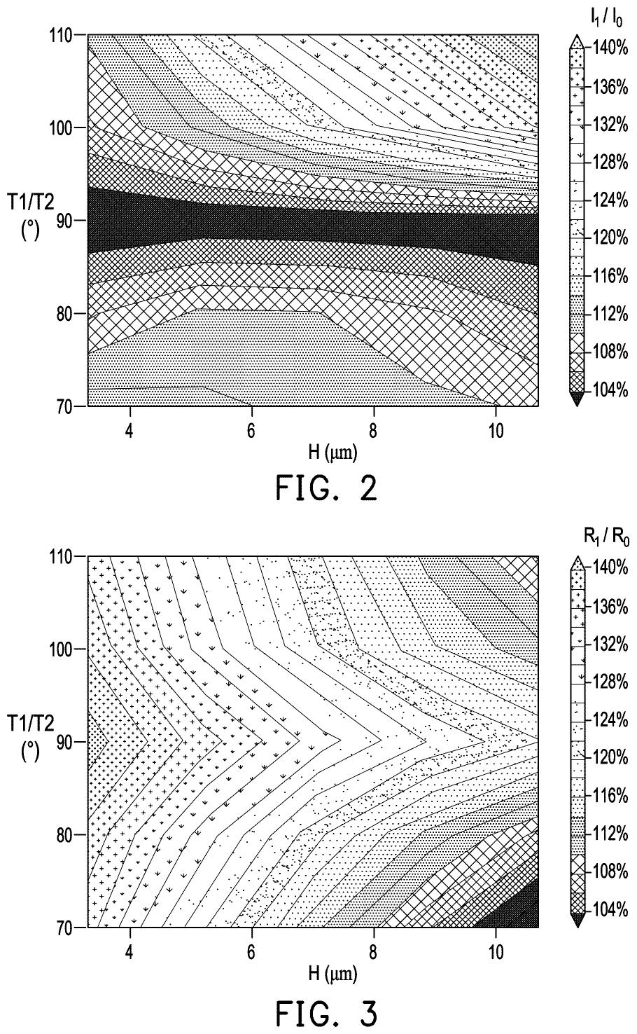

FIG. 2 shows the ratio I₁/I₀ of the forward brightness I₁ of the display apparatus 10 of an embodiment of the disclosure with the spacer 142 having various heights H (marked in FIG. 1) and various first angles T1/second angles T2 to the forward brightness I₀ of a display apparatus of a comparative example, where the difference between the display apparatus of the comparative example (not illustrated) and the display apparatus 10 of the embodiment is only that: the display apparatus of the comparative example does not include the spacer 142 that abuts against the light-emitting element 122.

Referring to FIG. 1 and FIG. 2, from the data in FIG. 2, it is known that regardless of whether the first angle T1 and/or the second angle T2 of the spacer 142 of the display apparatus 10 of the embodiment is greater than, less than, or equal to 90°, the spacer 142 that abuts against the light-emitting element 122 helps to improve the forward luminous efficacy of the light-emitting element 122. The gain in improving forward luminous efficacy with the spacer 142 having certain heights H and certain first angles T1/second angles T2 may even reach 40%. In some embodiments, the height H of the spacer 142 may fall in the range of 3 μm to 11 μm; preferably, the height H of the spacer 142 may fall in the range of 7 μm to 11 μm. In some embodiments, the first angle T1/second angle T2 of the spacer 142 may fall in the range of 70° to 110°; preferably, the first angle T1/second angle T2 of the spacer 142 may fall in the range of 100° to 110°.

FIG. 3 shows the ratio R₁/R₀ of the reflectivity R₁ of the display apparatus 10 of an embodiment of the disclosure with the spacer 142 having various heights H and various first angles T1/second angles T2 to the reflectivity R₀ of a display apparatus of a comparative example, where the difference between the display apparatus of the comparative example (not illustrated) and the display apparatus 10 of the embodiment is only that: the display apparatus of the comparative example does not include the spacer 142 that abuts against the light-emitting element 122.

Referring to FIG. 1 and FIG. 3, from the data in FIG. 3, it is known that regardless of what the height H and the first angle T1/second angle T2 of the spacer 142 are, the spacer 142 that abuts against the light-emitting element 122 has minimal impact on the reflectivity R₁ of the display apparatus 10. In other words, the spacer 142 that abuts against the light-emitting element 122 will not cause excessive increase in the reflectivity R₁ of the display apparatus 10.

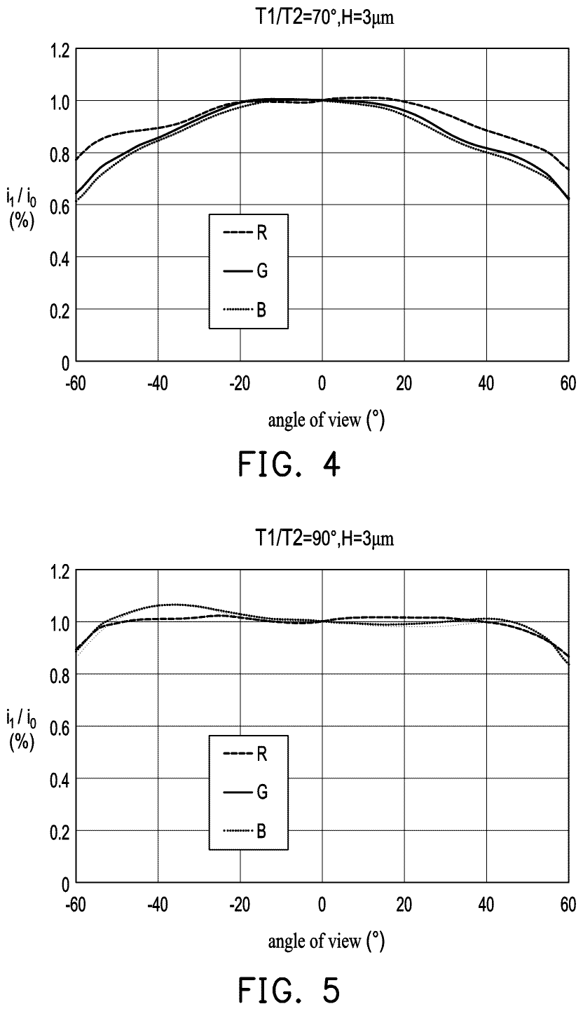

FIG. 4 shows the ratio i₁/i₀ of the brightness i₁ of the display apparatus 10 of an embodiment of the disclosure with the spacer 142 having a height H=3 μm and a first angle T1/second angle T2=70° at various angles of view to the brightness i₀ of a display apparatus of a comparative example at the same angles of view, where the difference between the display apparatus of the comparative example (not illustrated) and the display apparatus 10 of the embodiment is only that: the display apparatus of the comparative example does not include the spacer 142 that abuts against the light-emitting element 122. The curve R in FIG. 4 represents the relationship between various angles of view and the ratio of the brightness of the first colored light of the display apparatus 10 of the embodiment to the brightness of the first colored light of the display apparatus of the comparative example. The curve G in FIG. 4 represents the relationship between various angles of view and the ratio of the brightness of the second colored light of the display apparatus 10 of the embodiment to the brightness of the second colored light of the display apparatus of the comparative example. The curve B in FIG. 4 represents the relationship between various angles of view and the ratio of the brightness of the third colored light of the display apparatus 10 of the embodiment to the brightness of the third colored light of the display apparatus of the comparative example.

FIG. 5 shows the ratio ivio of the brightness i₁ of the display apparatus 10 of an embodiment of the disclosure with the spacer 142 having a height H=3 μm and a first angle T1/second angle T2=90° at various angles of view to the brightness i₀ of a display apparatus of a comparative example at the same angles of view, where the difference between the display apparatus of the comparative example (not illustrated) and the display apparatus 10 of the embodiment is only that: the display apparatus of the comparative example does not include the spacer 142 that abuts against the light-emitting element 122. The curve R in FIG. 5 represents the relationship between various angles of view and the ratio of the brightness of the first colored light of the display apparatus 10 of the embodiment to the brightness of the first colored light of the display apparatus of the comparative example. The curve G in FIG. 5 represents the relationship between various angles of view and the ratio of the brightness of the second colored light of the display apparatus 10 of the embodiment to the brightness of the second colored light of the display apparatus of the comparative example. The curve B in FIG. 5 represents the relationship between various angles of view and the ratio of the brightness of the third colored light of the display apparatus 10 of the embodiment to the brightness of the third colored light of the display apparatus of the comparative example.

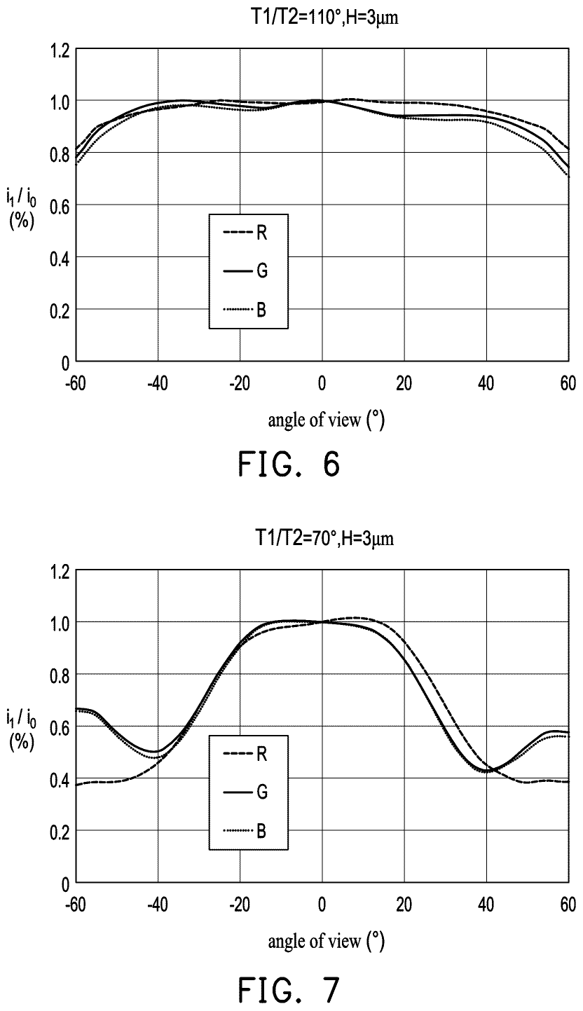

FIG. 6 shows the ratio i₁/i₀ of the brightness i₁ of the display apparatus 10 of an embodiment of the disclosure with the spacer 142 having a height H=3 μm and a first angle T1/second angle T2=110° at various angles of view to the brightness i₀ of a display apparatus of a comparative example at the same angles of view, where the difference between the display apparatus of the comparative example (not illustrated) and the display apparatus 10 of the embodiment is only that: the display apparatus of the comparative example does not include the spacer 142 that abuts against the light-emitting element 122. The curve R in FIG. 6 represents the relationship between various angles of view and the ratio of the brightness of the first colored light of the display apparatus 10 of the embodiment to the brightness of the first colored light of the display apparatus of the comparative example. The curve G in FIG. 6 represents the relationship between various angles of view and the ratio of the brightness of the second colored light of the display apparatus 10 of the embodiment to the brightness of the second colored light of the display apparatus of the comparative example. The curve B in FIG. 6 represents the relationship between various angles of view and the ratio of the brightness of the third colored light of the display apparatus 10 of the embodiment to the brightness of the third colored light of the display apparatus of the comparative example.

FIG. 7 shows the ratio i₁/i₀ of the brightness i₁ of the display apparatus 10 of an embodiment of the disclosure with the spacer 142 having a height H=11 μm and a first angle T1/second angle T2==70° at various angles of view to the brightness i₀ of a display apparatus of a comparative example at the same angles of view, where the difference between the display apparatus of the comparative example (not illustrated) and the display apparatus 10 of the embodiment is only that: the display apparatus of the comparative example does not include the spacer 142 that abuts against the light-emitting element 122. The curve R in FIG. 7 represents the relationship between various angles of view and the ratio of the brightness of the first colored light of the display apparatus 10 of the embodiment to the brightness of the first colored light of the display apparatus of the comparative example. The curve G in FIG. 7 represents the relationship between various angles of view and the ratio of the brightness of the second colored light of the display apparatus 10 of the embodiment to the brightness of the second colored light of the display apparatus of the comparative example. The curve B in FIG. 7 represents the relationship between various angles of view and the ratio of the brightness of the third colored light of the display apparatus 10 of the embodiment to the brightness of the third colored light of the display apparatus of the comparative example.

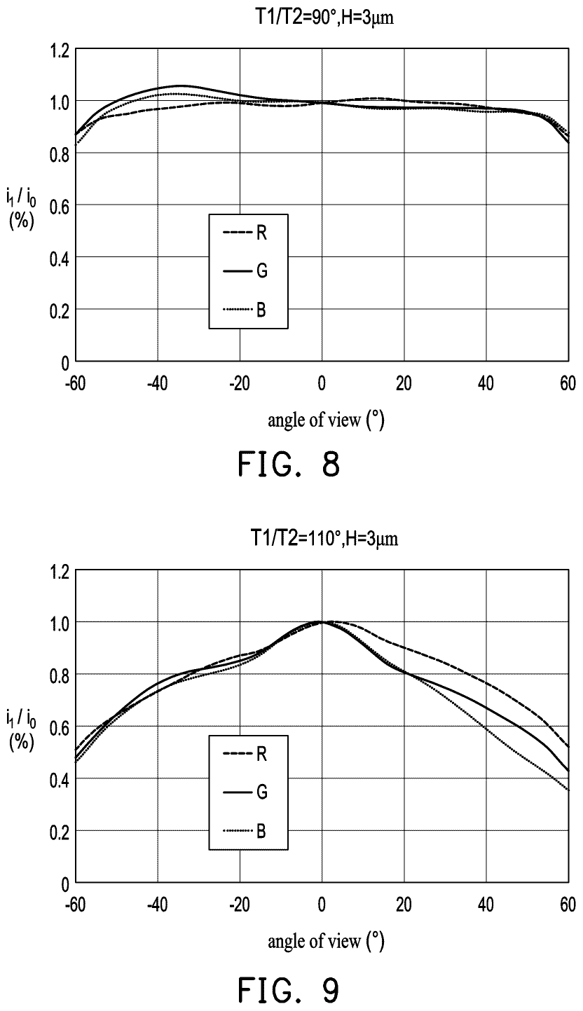

FIG. 8 shows the ratio i₁/i₀ of the brightness i₁ of the display apparatus 10 of an embodiment of the disclosure with the spacer 142 having a height H=11 μm and a first angle T1/second angle T2=90° at various angles of view to the brightness i₀ of a display apparatus of a comparative example at the same angles of view, where the difference between the display apparatus of the comparative example (not illustrated) and the display apparatus 10 of the embodiment is only that: the display apparatus of the comparative example does not include the spacer 142 that abuts against the light-emitting element 122. The curve R in FIG. 8 represents the relationship between various angles of view and the ratio of the brightness of the first colored light of the display apparatus 10 of the embodiment to the brightness of the first colored light of the display apparatus of the comparative example. The curve G in FIG. 8 represents the relationship between various angles of view and the ratio of the brightness of the second colored light of the display apparatus 10 of the embodiment to the brightness of the second colored light of the display apparatus of the comparative example. The curve B in FIG. 8 represents the relationship between various angles of view and the ratio of the brightness of the third colored light of the display apparatus 10 of the embodiment to the brightness of the third colored light of the display apparatus of the comparative example.

FIG. 9 shows the ratio i₁/i₀ of the brightness i₁ of the display apparatus 10 of an embodiment of the disclosure with the spacer 142 having a height H=11 μm and a first angle T1/second angle T2=110° at various angles of view to the brightness i₀ of a display apparatus of a comparative example at the same angles of view, where the difference between the display apparatus of the comparative example (not illustrated) and the display apparatus 10 of the embodiment is only that: the display apparatus of the comparative example does not include the spacer 142 that abuts against the light-emitting element 122. The curve R in FIG. 9 represents the relationship between various angles of view and the ratio of the brightness of the first colored light of the display apparatus 10 of the embodiment to the brightness of the first colored light of the display apparatus of the comparative example. The curve G in FIG. 9 represents the relationship between various angles of view and the ratio of the brightness of the second colored light of the display apparatus 10 of the embodiment to the brightness of the second colored light of the display apparatus of the comparative example. The curve B in FIG. 9 represents the relationship between various angles of view and the ratio of the brightness of the third colored light of the display apparatus 10 of the embodiment to the brightness of the third colored light of the display apparatus of the comparative example.

From the data in FIG. 4 to FIG. 9, it may be known that when the first angle T1/second angle T2 of the spacer 142 is greater than 90°, the display apparatus 10 may have better wide angle of view properties.

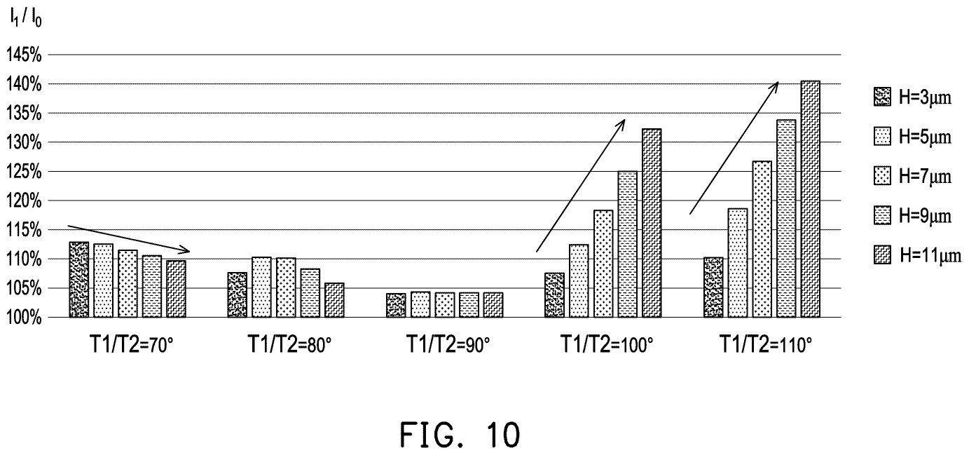

FIG. 10 presents in a columnar method the ratio I₁/I₀ of the forward brightness I₁ of the display apparatus 10 of an embodiment of the disclosure with the spacer 142 having various heights H and various first angles T1/second angles T2 to the forward brightness I₀ of a display apparatus of a comparative example, where the difference between the display apparatus of the comparative example (not illustrated) and the display apparatus 10 of the embodiment is only that: the display apparatus of the comparative example does not include the spacer 142 that abuts against the light-emitting element 122. In FIG. 10, a plurality of data are grouped by the value of the first angle T1/second angle T2 of the spacer 142.

Referring to FIG. 1 and FIG. 10, from the data in FIG. 10, it may be known that when the first angle T1/second angle T2 of the spacer 142 is less than 90°, the forward brightness I₁ of the display apparatus 10 has a positive correlation with the height H of the spacer 142; when the first angle T1/second angle T2 of the spacer 142 equals 90°, the forward brightness I₁ of the display apparatus 10 is almost not affected by the height H of the spacer 142; when the first angle T1/second angle T2 of the spacer 142 is greater than 90°, the forward brightness I₁ of the display apparatus 10 has a positive correlation with the height H of the spacer 142, I₁/I₀=A×H+B, where A falls in the range of 0.03 to 0.04, and B falls in the range of 0.97 to 1.

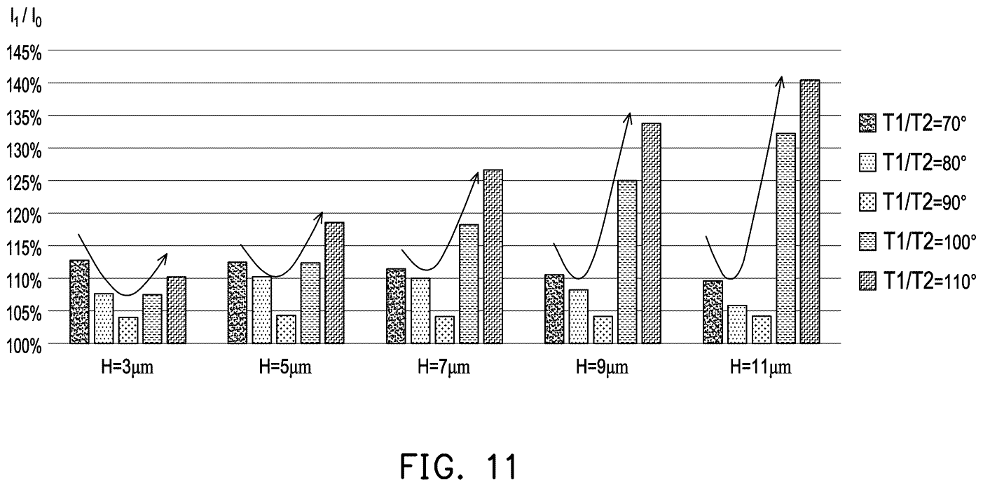

FIG. 11 presents in a columnar method the ratio I₁/I₀ of the forward brightness I₁ of the display apparatus 10 of an embodiment of the disclosure with the spacer 142 having various heights H and various first angles T1/second angles T2 to the forward brightness I₀ of a display apparatus of a comparative example, where the difference between the display apparatus of the comparative example (not illustrated) and the display apparatus 10 of the embodiment is only that: the display apparatus of the comparative example does not include the spacer 142 that abuts against the light-emitting element 122. In FIG. 11, a plurality of data are grouped by the height H of the spacer 142.

Referring to FIG. 1 and FIG. 11, from the data in FIG. 11, it may be known that the first angle T1/second angle T2 of the spacer 142 has a quadratic curve correlation with the forward brightness I1 of the display apparatus 10. I₁/I₀=a₁×(T1)²−a₂×(T1)+b, where a₁ falls in the range of 0.0003 to 0.0004, a₂ falls in the range of 0.03 to 0.07, and b falls in the range of 2.6 to 3.6.

It must be explained here that the reference numerals and a part of the contents in the previous embodiment are applicable to the following embodiments, in which identical reference numerals indicate identical or similar components, and repeated descriptions of the same technical contents are omitted. For the detailed descriptions of the omitted parts, reference can be found in the previous embodiment, and no repeated description is contained in the following embodiments.

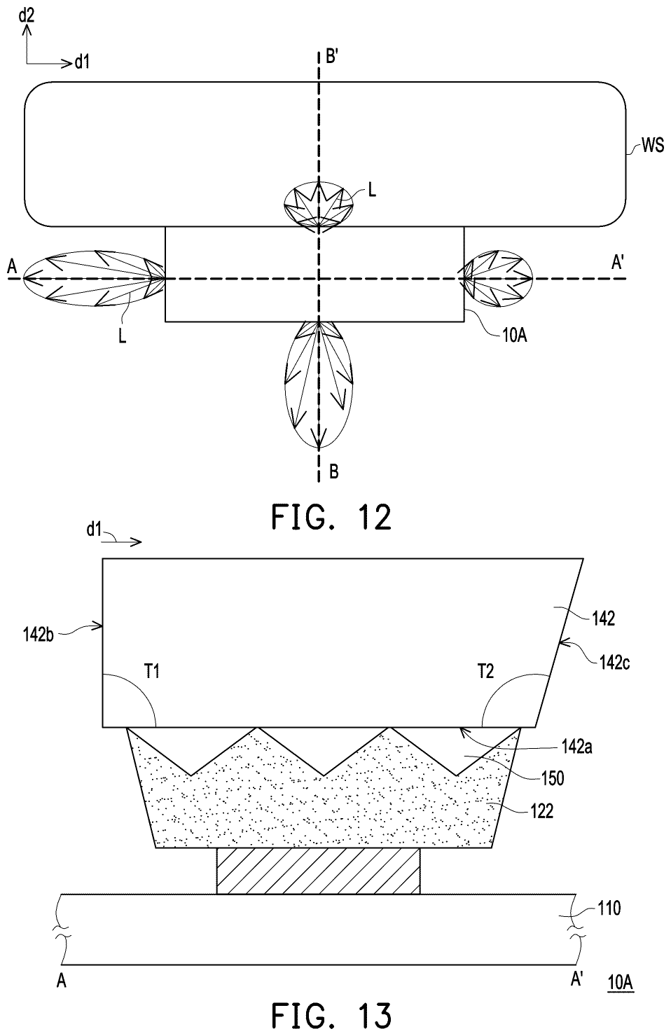

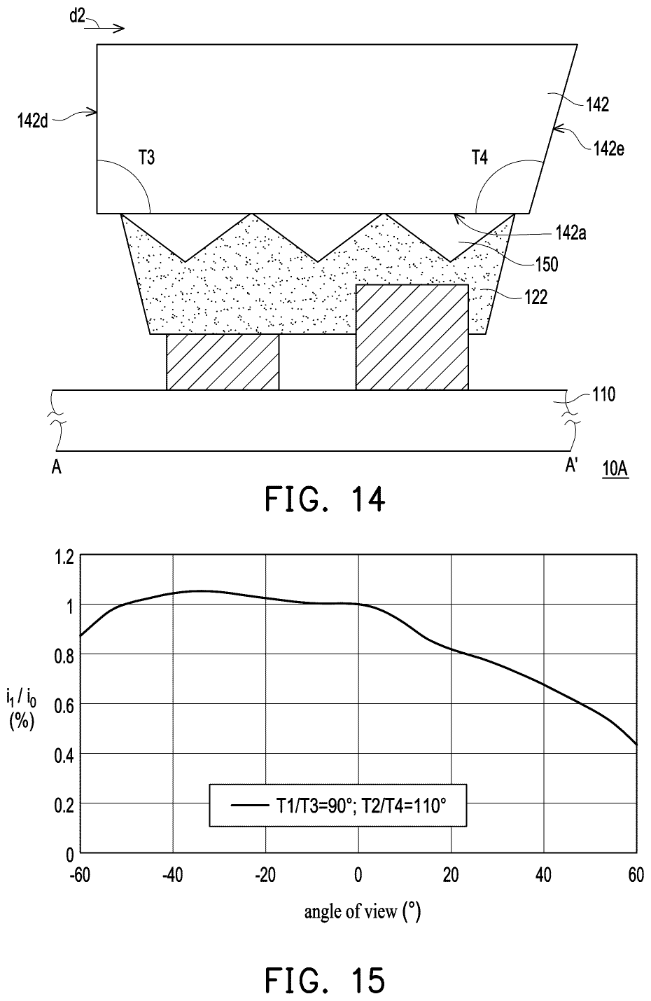

FIG. 12 is a schematic front view of a display apparatus 10A according to another embodiment of the disclosure. FIG. 13 is a schematic cross-sectional view of a display apparatus 10A according to another embodiment of the disclosure. FIG. 13 corresponds to the line A-A′ of FIG. 12. FIG. 14 is a schematic cross-sectional view of a display apparatus 10A according to another embodiment of the disclosure. FIG. 14 corresponds to the line B-B′ of FIG. 12. FIG. 15 shows the relationship between the angle of view and the ratio i₁/i₀ of the display apparatus 10 of another embodiment of the disclosure when the first angle T1, the second angle T2, the third angle T3, and the fourth angle T4 of its light-emitting element 122 are at various values, where i₁/i₀ refers to the ratio of the brightness i₁ of the display apparatus 10A at various angles of view to the brightness i₀ of a display apparatus of a comparative example at the same angles of view, and the difference between the display apparatus of the comparative example (not illustrated) and the display apparatus 10A of the embodiment is only that: the display apparatus of the comparative example does not include the spacer 142 that abuts against the light-emitting element 122.

Referring to FIG. 12, FIG. 13, and FIG. 14, the first sidewall 142b and the second sidewall 142c of each spacer 142 are arranged in a first direction d1, each spacer 142 further has a third sidewall 142d and a fourth sidewall 142e, the third sidewall 142d and the fourth sidewall 142e are arranged in a second direction d2, and the first direction dl and the second direction d2 intersect.

Referring to FIG. 12 and FIG. 13, the first sidewall 142b of each spacer 142 contains a first angle T1 within the material of the spacer 142. Each surface 142a of the spacer 142 and the second sidewall 142c of the spacer 142 contain a second angle T2 within the material of the spacer 142. In some embodiments, the first angle T1 is different from the second angle T2. Referring to FIG. 12, FIG. 13, and FIG. 15, for example, in some embodiments, the first sidewall 142b and the second sidewall 142c are arranged sequentially in the first direction d1. The first direction d1 is, for example, the direction from the driver's seat towards the passenger seat in a car. The first angle T1 is substantially equal to 90°, and the second angle T2 is substantially equal to 110° to guide a higher proportion of the light beam L emitted by the light-emitting element 122 towards the driver on the left side, which helps the driver to more clearly view the driving-related information displayed by the display apparatus 10. However, the disclosure is not limited thereto. In other embodiments not illustrated, it may also be that the second angle T2 is substantially equal to 90°, and the first angle T1 is substantially equal to 110° to guide a higher proportion of the light beam L emitted by the light-emitting element 122 towards the passenger on the right side, which helps the passenger to more clearly view the entertainment information displayed by the display apparatus 10.

Referring to FIG. 12 and FIG. 14, each surface 142a of the spacer 142 and the third sidewall 142d of the spacer 142 contain a third angle T3 within the material of the spacer 142. Each surface 142a of the spacer 142 and the fourth sidewall 142e of the spacer 142 contain a fourth angle T4 within the material of the spacer 142. In some embodiments, the third angle T3 is different from the fourth angle T4. Referring to FIG. 12, FIG. 14, and FIG. 15, for example, in some embodiments, the third sidewall 142d and the fourth sidewall 142e are arranged sequentially in the second direction d2. The second direction d2 is, for example, the direction from the car floor towards the car roof. The third angle T3 is substantially equal to 90°, and the fourth angle T4 is substantially equal to 110° to make a lower proportion of the light beam L emitted by the light-emitting element 122 emit towards a windshield WS to reduce reflection, which helps the driver to more clearly view the driving-related information displayed by the display apparatus 10.

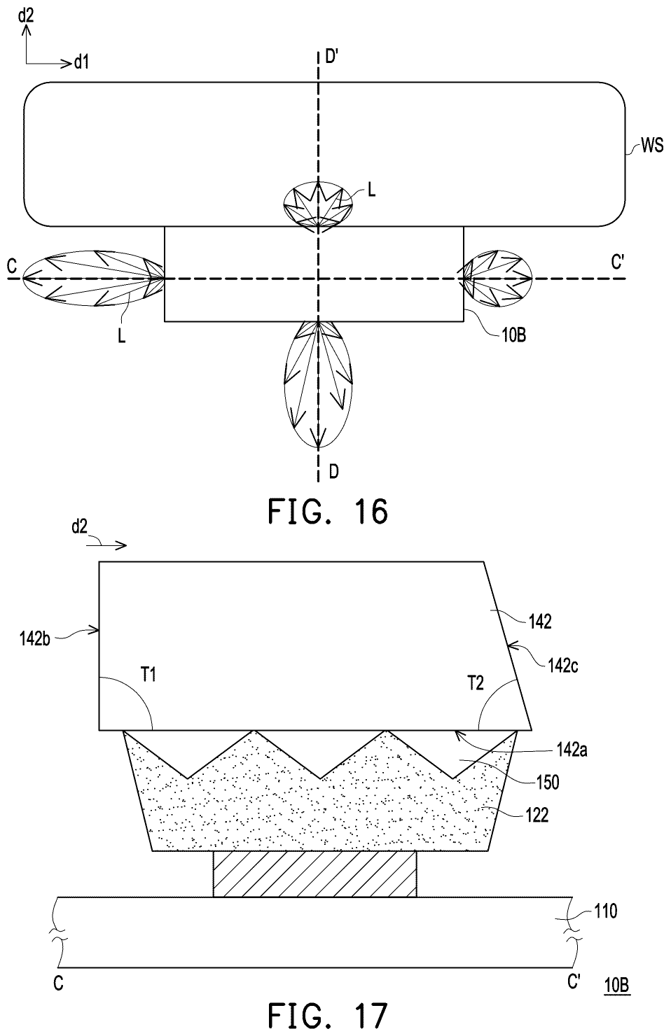

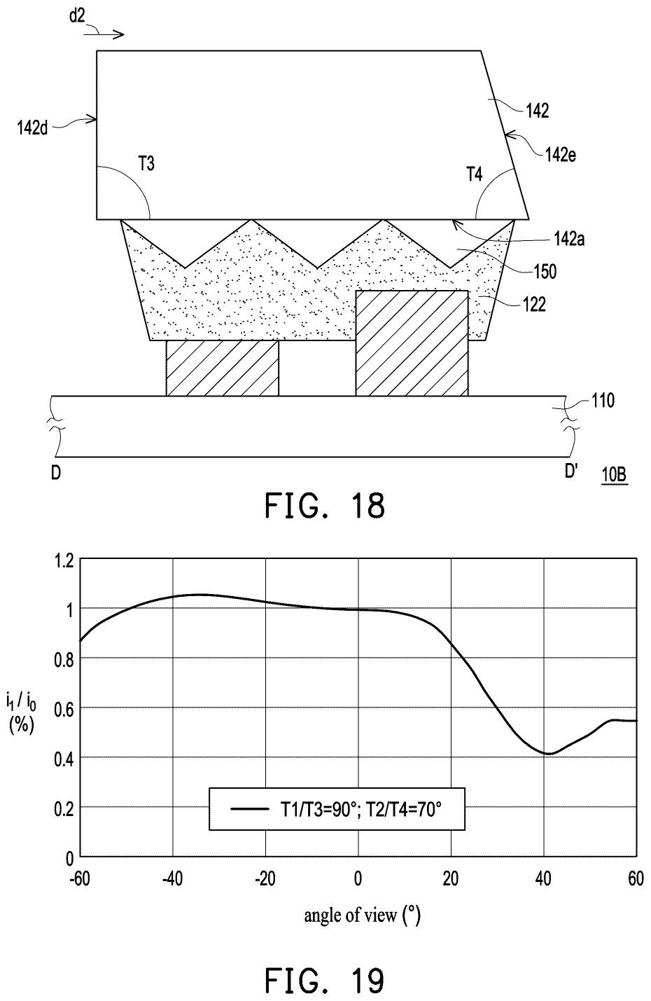

FIG. 16 is a schematic front view of a display apparatus 10B according to yet another embodiment of the disclosure. FIG. 17 is a schematic cross-sectional view of a display apparatus 10B according to yet another embodiment of the disclosure. FIG. 17 corresponds to the line C-C′ of FIG. 16. FIG. 18 is a schematic cross-sectional view of a display apparatus 10B according to yet another embodiment of the disclosure. FIG. 18 corresponds to the line D-D′ of FIG. 16. FIG. 19 shows the relationship between the angle of view and the ratio i₁/i₀ of the display apparatus 10B of yet another embodiment of the disclosure when the first angle T1, the second angle T2, the third angle T3, and the fourth angle T4 of its light-emitting element 122 are at various values, where i₁/i₀ refers to the ratio of the brightness i₁ of the display apparatus 10B at various angles of view to the brightness i₀ of the aforementioned display apparatus of the comparative example at the same angle of view, and the difference between the display apparatus of the comparative example (not illustrated) and the display apparatus 10B of the embodiment is only that: the display apparatus of the comparative example does not include the spacer 142 that abuts against the light-emitting element 122.

The display apparatus 10B in FIG. 16, FIG. 17, and FIG. 18 is similar to the display apparatus 10A in FIG. 12, FIG. 13, and FIG. 14. The difference between the two is that: the second angle T2 of the spacer 142 of the display apparatus 10B is different from the second angle T2 of the spacer 142 of the display apparatus 10A, and the fourth angle T4 of the spacer 142 of the display apparatus 10B is different from the fourth angle T4 of the spacer 142 of the display apparatus 10A. Specifically, in the embodiment of FIG. 12, FIG. 13, and FIG. 14, the second angle T2 and the fourth angle T4 of the spacer 142 are greater than 90° (for example,) 110°; in the embodiment of FIG. 16, FIG. 17, and FIG. 18, the second angle T2 of the spacer 142 is less than 90° (for example,) 70°, but the disclosure is not limited thereto.

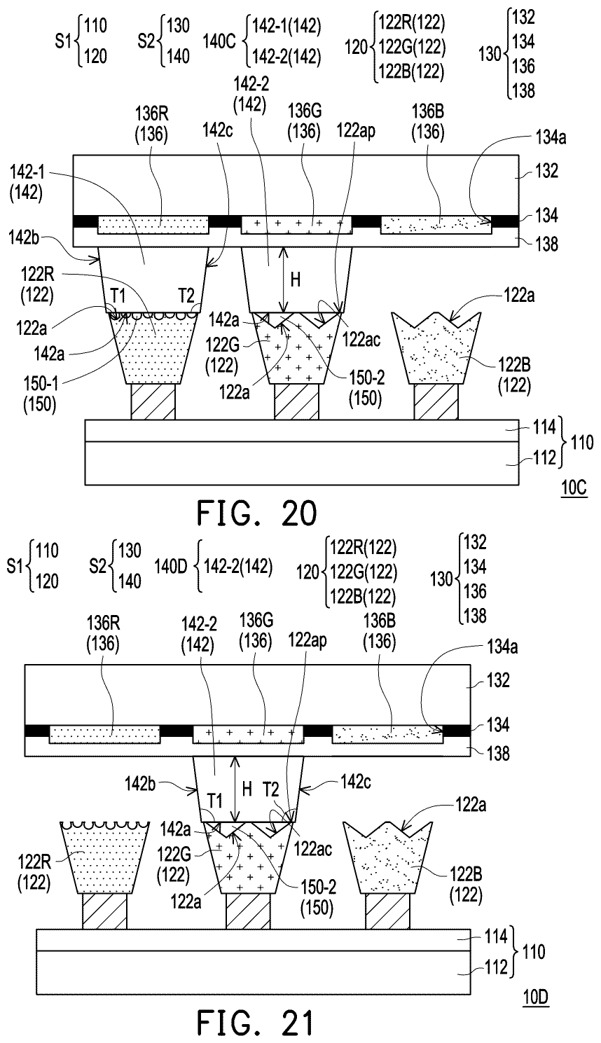

FIG. 20 is a schematic cross-sectional view of a display apparatus 10C according to still another embodiment of the disclosure. The display apparatus 10C in FIG. 20 is similar to the display apparatus 10 in FIG. 1. The difference between the two is that: in the embodiment of FIG. 20, a spacer unit 140C may selectively not include the third spacer 142-3 of FIG. 1.

FIG. 21 is a schematic cross-sectional view of a display apparatus 10D according to an embodiment of the disclosure. The display apparatus 10D in FIG. 21 is similar to the display apparatus 10 in FIG. 1. The difference between the two is that: in the embodiment of FIG. 21, a spacer unit 140D may selectively not include the first spacer 142-1 and the third spacer 142-3 of FIG. 1.

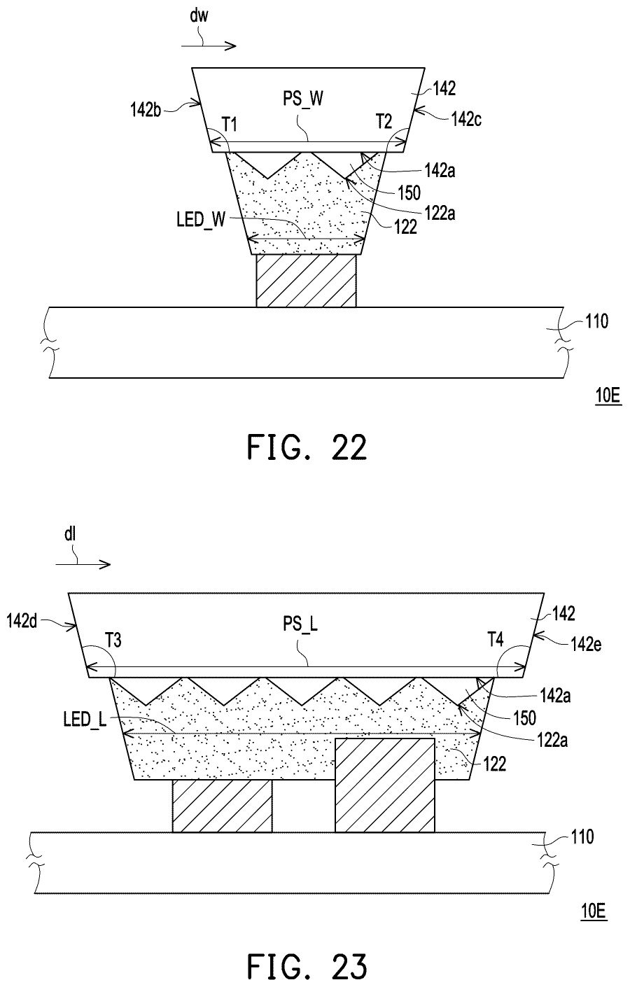

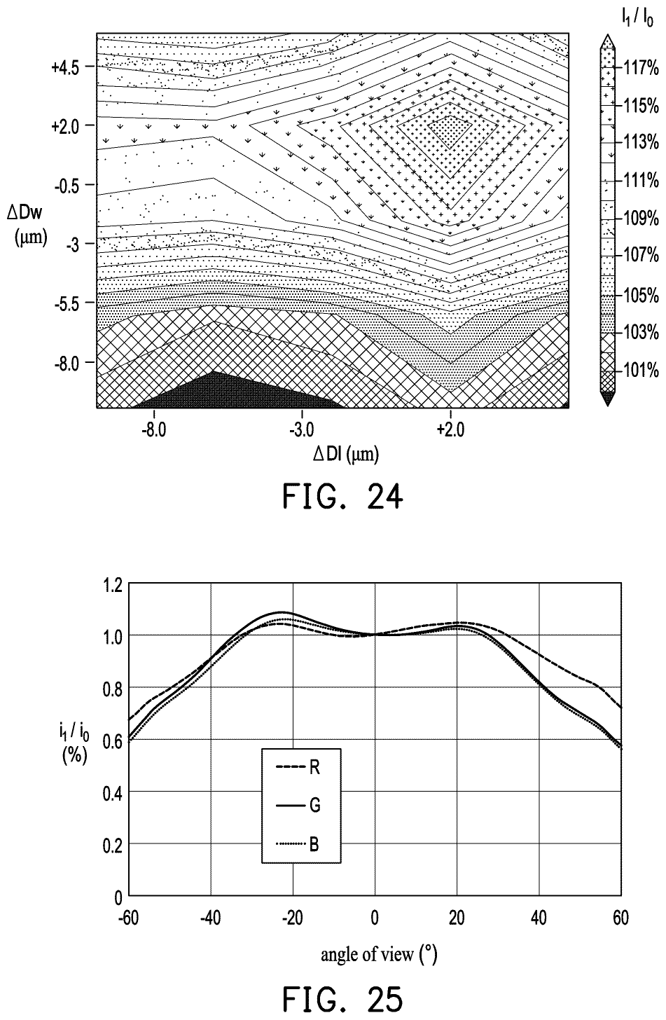

FIG. 22 is a schematic cross-sectional view of a display apparatus 10E according to another embodiment of the disclosure. Specifically, FIG. 22 shows a profile of the light-emitting element 122 and the spacer 142 in the width direction dw of the light-emitting element 122. FIG. 23 is a schematic cross-sectional view of a display apparatus 10E according to another embodiment of the disclosure. Specifically, FIG. 23 shows a profile of the light-emitting element 122 and the spacer 142 in the length direction dl of the light-emitting element 122. FIG. 24 shows the relationship between the difference value ΔDw of the width PS_W of the spacer 142 and the width LED_W of the light-emitting element 122 in the width direction dw of the light-emitting element 122, and the difference value ΔDl of the length PS_L of the spacer 142 and the length LED_L of the light-emitting element 122 in the length direction dl of the light-emitting element 122, with the ratio I₁/I₀, where ΔDw=(PS_W)−(LED_W), ΔD1=(PS_L)−(LED_L), the ratio I₁/I₀ refers to the ratio of the forward brightness I₁ of the display apparatus 10E of this embodiment to the forward brightness I₀ of the display apparatus of the comparative example, and the difference between the display apparatus of the comparative example (not illustrated) and the display apparatus 10E of the embodiment is only that: the display apparatus of the comparative example does not include the spacer 142 that abuts against the light-emitting element 122.

Referring to FIG. 22, FIG. 23, and FIG. 24, from the data in FIG. 24, it may be known that, in some embodiments, if the difference value ΔDw between the width PS_W of the spacer 142 and the width LED_W of the light-emitting element 122 in the width direction dw of the light-emitting element 122 is +2 μm, and the difference value ΔDl between the length PS_L of the spacer 142 and the length LED_L of the light-emitting element 122 in the length direction dl of the light-emitting element 122 is +2 μum, the display apparatus 10E may have the optimal gain in forward luminous efficacy.

FIG. 25 shows the ratio i₁/i₀ of the brightness i₁ of the display apparatus 10E of another embodiment of the disclosure with ΔDw=+2 μm and ΔDl=+2 μm at various angles of view to the brightness i₀ of the display apparatus of the comparative example at the same angle of view, where the difference between the display apparatus of the comparative example (not illustrated) and the display apparatus 10E of the embodiment is only that: the display apparatus of the comparative example does not include the spacer 142 that abuts against the light-emitting element 122. The curve R in FIG. 25 represents the relationship between various angles of view and the ratio of the brightness of the first colored light of the display apparatus 10E of the embodiment to the brightness of the first colored light of the display apparatus of the comparative example. The curve G in FIG. 25 represents the relationship between various angles of view and the ratio of the brightness of the second colored light of the display apparatus 10E of the embodiment to the brightness of the second colored light of the display apparatus of the comparative example. The curve B in FIG. 25 represents the relationship between various angles of view and the ratio of the brightness of the third colored light of the display apparatus 10E of the embodiment to the brightness of the third colored light of the display apparatus of the comparative example.

Referring to FIG. 22, FIG. 23, FIG. 24, and FIG. 25, from the data in FIG. 24 and FIG. 25, it may be known that, in some embodiments, if the difference value ΔDw between the width PS_W of the spacer 142 and the width LED_W of the light-emitting element 122 in the width direction dw of the light-emitting element 122 is +2 μm, and the difference value ΔDl between the length PS_L of the spacer 142 and the length LED_L of the light-emitting element 122 in the length direction dl of the light-emitting element 122 is +2 μm, the display apparatus 10E may not only enhance the forward luminous efficacy but also maintain the wide angle of view characteristic.

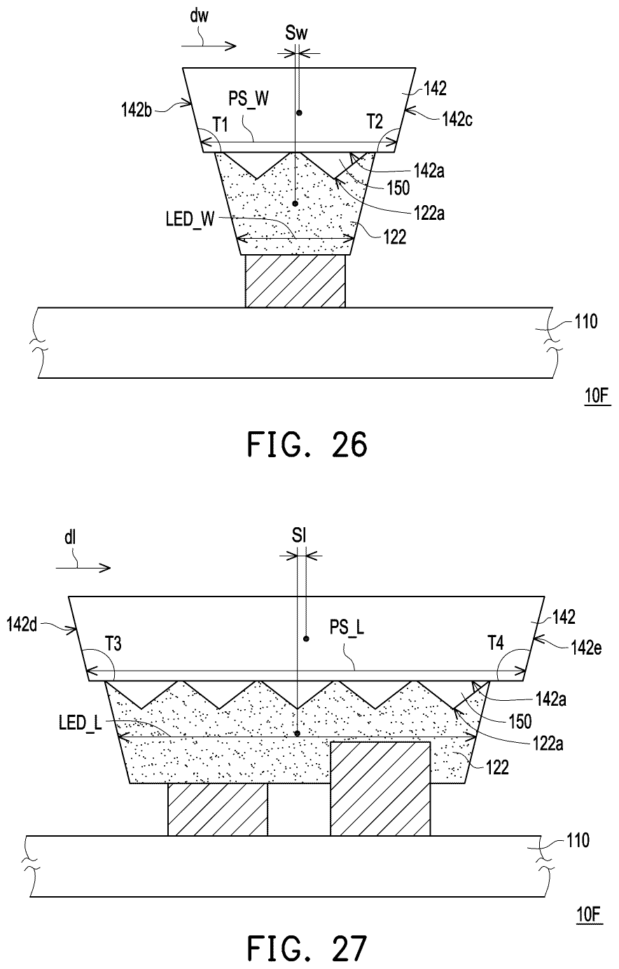

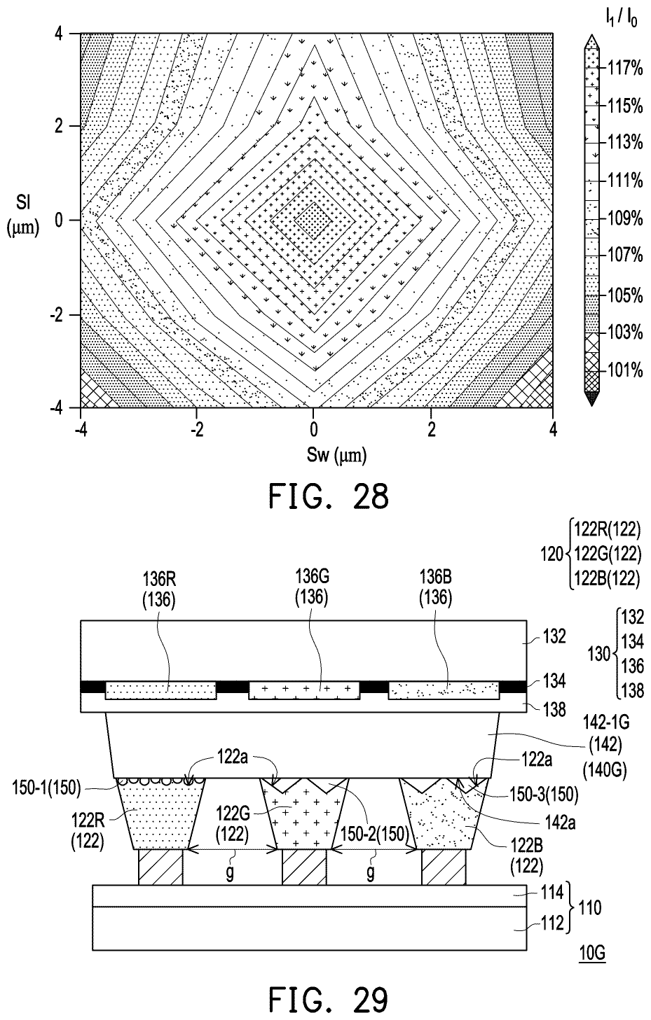

FIG. 26 is a schematic cross-sectional view of a display apparatus 10F according to yet another embodiment of the disclosure. In particular, FIG. 26 shows the profile of the light-emitting element 122 and the spacer 142 in the width direction dw of the light-emitting element 122. FIG. 27 is a schematic cross-sectional view of a display apparatus 10F according to yet another embodiment of the disclosure. In particular, FIG. 27 shows the profile of the light-emitting element 122 and the spacer 142 in the length direction dl of the light-emitting element 122. FIG. 28 shows the relationship between the ratio I₁/I₀ and the offset Sw of the light-emitting element 122 and the spacer 142 in the width direction dw of the light-emitting element 122 and the offset Sl of the light-emitting element 122 and the spacer 142 in the length direction dl of the light-emitting element 122, where the ratio I₁/I₀ refers to the ratio of the forward brightness I₁ of the display apparatus 10F of this embodiment to the forward brightness I₀ of the display apparatus of the comparative example, and the difference between the display apparatus of the comparative example (not illustrated) and the display apparatus 10F of the embodiment is only that: the display apparatus of the comparative example does not include the spacer 142 that abuts against the light-emitting element 122.

Referring to FIG. 26, FIG. 27, and FIG. 28, from the data in FIG. 28, it may be known that, in some embodiments, when the offset Sw between the light-emitting element 122 and the spacer 142 in the width direction dw of the light-emitting element 122 and the offset SI between the light-emitting element 122 and the spacer 142 in the length direction dl of the light-emitting element 122 are less than 2 μm, the display apparatus 10F may maintain better gain in forward luminous efficacy.

FIG. 29 is a schematic cross-sectional view of a display apparatus 10G according to still another embodiment of the disclosure. The display apparatus 10G in FIG. 29 is similar to the display apparatus 10 in FIG. 1. The difference between the two is that: in the embodiment of FIG. 29, the spacer unit 140G may selectively not include the second spacer 142-2 and the third spacer 142-3 of FIG. 1, the spacer unit 140G includes the first spacer 142-1G, the first spacer 142-1G abuts against the light-emitting surface 122a of the first light-emitting element 122R, the light-emitting surface 122a of the second light-emitting element 122G and the light-emitting surface 122a of the third light-emitting element 122B, and the same first spacer 142-1G overlaps with a plurality of gaps g between a plurality of light-emitting elements 122.

What is claimed is:

1. A display apparatus, comprising:
a driving backplane;
a pixel unit, comprising a plurality of light-emitting elements, wherein the light-emitting elements are disposed on the driving backplane and electrically connected to the driving backplane, and the light-emitting elements comprise at least a first light-emitting element;
an opposite substrate, disposed opposite to the driving backplane; and
a spacer unit, disposed on the opposite substrate, wherein the spacer unit overlaps with the pixel unit, the spacer unit comprises at least a first spacer, a surface of the first spacer and a light-emitting surface of the first light-emitting element abut each other, there is a first low refractive index layer between the surface of the first spacer and the light-emitting surface of the first light-emitting element, and a refractive index of the first low refractive index layer is less than a refractive index of the first spacer.

2. The display apparatus according to claim 1, wherein the light-emitting surface of the first light-emitting element has a plurality of protrusions and a plurality of recesses defined by the protrusions, and the first spacer contacts the protrusions of the light-emitting surface of the first light-emitting element.

3. The display apparatus according to claim 1, wherein the light-emitting surface of the first light-emitting element has a plurality of protrusions and a plurality of recesses defined by the protrusions, and at least a portion of the first low refractive index layer is disposed in the recesses of the light-emitting surface of the first light-emitting element.

4. The display apparatus according to claim 1, wherein the first spacer further has a first sidewall, the surface of the first spacer and the first sidewall of the first spacer contain a first angle within a material of the first spacer, and the first angle is greater than or equal to 70° and less than or equal to 110°.

5. The display apparatus according to claim 1, wherein the surface of the first spacer and a first sidewall of the first spacer contain a first angle within a material of the first spacer, and the first angle is greater than 90°.

6. The display apparatus according to claim 1, wherein the first spacer further has a first sidewall and a second sidewall opposite to each other, the surface of the first spacer and the first sidewall of the first spacer contain a first angle within a material of the first spacer, the surface of the first spacer and the second sidewall of the first spacer contain a second angle within a material of the first spacer, and the first angle is different from the second angle.

7. The display apparatus according to claim 6, wherein the first sidewall and the second sidewall of the first spacer are arranged in a first direction, the first spacer further has a third sidewall and a fourth sidewall, the third sidewall and the fourth sidewall are arranged in a second direction, the first direction and the second direction intersect, the surface of the first spacer and the third sidewall of the first spacer contain a third angle within a material of the first spacer, the surface of the first spacer and the fourth sidewall of the first spacer contain a fourth angle within a material of the first spacer, and the third angle is different from the fourth angle.

8. The display apparatus according to claim 1, wherein the spacer unit further comprises a second spacer, the first spacer and the second spacer are separated, the light-emitting elements further comprise a second light-emitting element, a surface of the second spacer and a light-emitting surface of the second light-emitting element abut each other, there is a second low refractive index layer between the surface of the second spacer and the light-emitting surface of the second light-emitting element, and a refractive index of the second low refractive index layer is less than a refractive index of the second spacer.

9. The display apparatus according to claim 8, wherein the spacer unit further comprises a third spacer, the third spacer is separated from the first spacer and the second spacer, the light-emitting elements further comprise a third light-emitting element, a surface of the third spacer and a light-emitting surface of the third light-emitting element abut each other, there is a third low refractive index layer between the surface of the third spacer and the light-emitting surface of the third light-emitting element, and a refractive index of the third low refractive index layer is less than a refractive index of the third spacer.

10. The display apparatus according to claim 1, wherein the light-emitting elements further comprise a second light-emitting element and a third light-emitting element, the surface of the same first spacer further abuts against a light-emitting surface of the second light-emitting element and a light-emitting surface of the third light-emitting element, and the same first spacer overlaps with a plurality of gaps between the light-emitting elements.

11. A display apparatus, comprising:
a driving backplane;
a pixel unit, comprising a plurality of light-emitting elements, wherein the light-emitting elements are disposed on the driving backplane and electrically connected to the driving backplane, and the light-emitting elements comprise at least a first light-emitting element;
an opposite substrate, disposed opposite to the driving backplane; and
a spacer unit, disposed on the opposite substrate, wherein the spacer unit overlaps with the pixel unit, the spacer unit comprises at least a first spacer, a surface of the first spacer and a light-emitting surface of the first light-emitting element abut each other, the light-emitting surface of the first light-emitting element has a plurality of protrusions and a plurality of recesses defined by the protrusions, and the first spacer contacts the protrusions of the light-emitting surface of the first light-emitting element.

12. The display apparatus according to claim 11, wherein the first spacer further has a first sidewall, the surface of the first spacer and the first sidewall of the first spacer contain a first angle within a material of the first spacer, and the first angle is greater than or equal to 70° and less than or equal to 110°.

13. The display apparatus according to claim 11, wherein the surface of the first spacer and a first sidewall of the first spacer contain a first angle within a material of the first spacer, and the first angle is greater than 90°.

14. The display apparatus according to claim 11, wherein the first spacer further has a first sidewall and a second sidewall opposite to each other, the surface of the first spacer and the first sidewall of the first spacer contain a first angle within a material of the first spacer, the surface of the first spacer and the second sidewall of the first spacer contain a second angle within a material of the first spacer, and the first angle is different from the second angle.

15. The display apparatus according to claim 11, wherein the light-emitting elements further comprise a second light-emitting element and a third light-emitting element, the surface of the same first spacer further abuts against a light-emitting surface of the second light-emitting element and a light-emitting surface of the third light-emitting element, and the same first spacer overlaps with a plurality of gaps between the light-emitting elements.
